(19) United States
(12) Patent Application Publication
(10) Pub. No.: US 2005/0110522 A1
(43) Pub. Date: May 26, 2005

(54) Multistage dynamic domino circuit with internally generated delay reset clock

(76) Inventor: George P. Hoekstra, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/718,891

(22) Filed: Nov. 21, 2003

(51) Int. Cl. H03K 19/096

(52) U.S. Cl. 326/95

(57) ABSTRACT

A multistage dynamic domino circuit includes a footed dynamic domino stage, a footless dynamic domino stage, and a internal delay circuit. The footed dynamic domino stage includes a first precharge circuit, evaluation logic, and a data output coupled to the evaluation logic. The footless dynamic domino stage includes evaluation logic including a data input coupled to the data output of the footed dynamic domino stage and a second precharge circuit. The second precharge circuit includes a first precharge device including a first current terminal and a control terminal coupled to a clock line. The second precharge circuit further includes a second precharge device including a first current terminal coupled to the first current terminal of first precharge device and a control terminal. The delay circuit includes an input coupled to the clock line and an output coupled to the control terminal of the second precharge device to provide a delayed version of a clock signal provided at the input of the delay circuit.

### BACKGROUND

The present disclosures generally relate to integrated circuits, and more particularly, to multistage dynamic domino circuits with an internally generated delay reset clock.

### RELATED ART

In a high speed design, dynamic circuits are often used. Often, multiple dynamic stages are used within a single clock phase. The second stage in this chain is often “footless,” where there is no clocked n-channel device. The second stage requires a clock which delays only the falling edge of the first stage clock. Accordingly, this avoids the precharge device being on at the same time while the evaluate device is still on.

However, it is critical that the rising edge of the second stage clock is not delayed more than the first stage evaluate time. If it is, then there is a delay penalty in the second stage. There will also be excess current in the precharge and evaluate devices. This time, the current is due to the precharge device being late to turn off. In one prior art device, to avoid these problems, a second stage clock (clk_delay) is generated outside of the dynamic block.

FIG. 1 is a schematic block diagram view of a prior art multistage dynamic domino circuit 10 having an internal falling edge delay clock. In particular, multistage dynamic domino logic circuit 10 includes a footed dynamic domino stage 12 and a footless dynamic domino stage 14. Footed dynamic domino stage 12 includes a precharge device 16, for example, a p-channel device. Precharge device 16 receives a clock signal (clk) on signal line 18. Dynamic domino footed stage 12 also includes evaluation logic 20 having a data input 22. An n-channel device 24 provides the foot for the footed stage of the multistage dynamic domino circuit 10 and has a first terminal coupled between evaluation logic 20 and system ground 33. Clock signal line 18 also couples to a control terminal of footed n-channel device 24.

Footed dynamic domino stage 12 further includes a keeper device 26, for example, a p-channel device. Keeper device 26 includes a control input coupled to an output 28 of stage 12. In addition, an inverter 30 couples between the evaluation logic 20 and output 28. Furthermore, keeper device 26 also includes terminals coupled between system voltage supply potential (V_{DD}) 32 and evaluation logic 20.

Footless dynamic domino stage 14 includes precharge device 34 and a clock delay 36, wherein clock delay 36 has an output (clk_delay) 38. Clock delay 36 includes a falling edge delay 40, a NOR gate 42, and an inverter 44. Falling edge delay 40 includes, for example, serially coupled first and second inverters. NOR gate 42 receives a first input corresponding to clock signal (clk) on signal line 18 and a second input corresponding to an output of the falling edge delay 40. An output of NOR gate 42 is input to inverter 44, which in turn provides an output signal on output (clk_delay) 38.

Footless dynamic domino stage 14 also includes evaluation logic 46 and a keeper device 48, for example, a p-channel device. Keeper device 48 includes a control input coupled to an output 50 of stage 14. In addition, an inverter 52 couples between the evaluation logic 46 and output 50. Furthermore, keeper device 48 also includes terminals coupled between system voltage supply potential (V_{DD}) 32 and evaluation logic 46. Evaluation logic is coupled to system ground via system ground 33, making the stage a footless stage.

FIG. 2 is a timing diagram of the multistage domino circuit of FIG. 1. As shown in FIG. 2, the first timing signal is that of a clock signal (clk) on signal line 18. The second timing signal is that of a signal on the output of falling edge delay 40. The third timing signal is that of clk_delay 38. The fourth timing signal is that of the output of footed stage 12 on signal line 28. The rising edge of the clock on signal line 18 signifies entering an evaluation phase, which controls the rising edge of both signal lines 38 and 28. An inherent weakness of this circuit is existence of a race condition between the signal on line 38 and the signal on line 28 switching high. If the delay on signal line 38 exceeds the delay on signal line 28, the circuit will not function at as high a frequency and there will be excess current through device 34 and the evaluation logic 46.

FIG. 3 is a schematic block diagram view of a prior art multistage domino circuit 60 having an external delay clock. In particular, multistage dynamic domino logic circuit 60 includes a footed dynamic domino stage 12 and a footless dynamic domino stage 14. Footed dynamic domino stage 12 includes a precharge device 16, for example, a p-channel device. Precharge device 16 receives a clock signal (clk1) on signal line 66. Dynamic domino footed stage 12 also includes evaluation logic 20 having a data input 22. An n-channel device 24 provides the foot for the footed stage of the multistage dynamic domino circuit 60 and has a first terminal coupled between evaluation logic 20 and system ground 33. Clock signal line 66 also couples to a control terminal of footed n-channel device 24.

Footed dynamic domino stage 12 further includes a keeper device 26, for example, a p-channel device. Keeper device 26 includes a control input coupled to an output 28 of stage 12. In addition, an inverter 30 couples between the evaluation logic 20 and output 28. Furthermore, keeper device 26 also includes terminals coupled between system voltage supply potential (V_{DD}) 32 and evaluation logic 20.

Circuit 60 includes external devices 64 and 68. Device 64 includes a buffer delay for delaying a clock input signal on line 62 and providing a output delayed clock (clk1) on signal line 66. Clock delay 68 includes a delay 40, a NOR gate 42, and an inverter 44. Delay 40 includes, for example, a falling edge delay of serially coupled first and second inverters. NOR gate 42 receives a first input corresponding to clock signal (clk) on signal line 62 and a second input corresponding to an output of the delay 40. An output of NOR gate 42 is input to inverter 44, which in turn provides an output signal on output (clk_delay) 70. Footless dynamic domino stage 14 includes precharge device 34 having a control input of precharge device 34 coupled to the output (clk_delay) of clock delay 68 on signal line 70.

Footless dynamic domino stage 14 also includes evaluation logic 46 and a keeper device 48, for example, a p-channel device. Keeper device 48 includes a control input coupled to an output 50 of stage 14. In addition, an inverter 52 couples between the evaluation logic 46 and output 50. Furthermore, keeper device 48 also includes terminals coupled between system voltage supply potential (V_{DD}) 32 and evaluation logic 46. Evaluation logic is coupled to system ground via system ground 33, making the stage a footless stage.

FIG. 4 is a timing diagram of the multistage domino circuit of FIG. 3. As shown in FIG. 4, the first timing signal is that of a clock signal (clk) on signal line 62. The second timing signal is that of a signal on the output of clock buffer 64 on signal line 66 (clk1). The third timing signal is that of signal (clk_delay) on line 70. The rising edge of the clock on signal line 62 signifies entering an evaluation phase, which controls the rising edge of both signal lines 66 (clk1) and 70 (clk_delay). An advantage of circuit 60 over that of circuit 10 of FIG. 1 is that the device 64 provides a buffer delay in the signal on line 66 (clk1) which prevents a race condition with the signal on line 70 (clk_delay).

However, an inherent weakness of circuit 60 is that the external placement of clock buffer 64 and clock delay 68 causes timing issues when the circuit is integrated into a chip. For example, signal line 66 (clk1) and signal line 70 (clk_delay) have different loads and wire lengths when routed at the chip level. As a result, the corresponding delays must be matched subsequent to being routed to their destinations within the chip, adding complexity to the chip design and manufacture thereof.

Accordingly, there is needed a circuit structure and method for overcoming the problems in the art as discussed above.

### SUMMARY

According to one embodiment of the present disclosure, a multistage dynamic domino circuit includes a footed dynamic domino stage, a footless dynamic domino stage, and a internal delay circuit. The footed dynamic domino stage includes a first precharge circuit, evaluation logic, and a data output coupled to the evaluation logic. The footless dynamic domino stage includes evaluation logic including a data input coupled to the data output of the footed dynamic domino stage and a second precharge circuit. The second precharge circuit includes a first precharge device including a first current terminal and a control terminal coupled to a clock line. The second precharge circuit further includes a second precharge device including a first current terminal coupled to the first current terminal of first precharge device and a control terminal. The delay circuit includes an input coupled to the clock line and an output coupled to the control terminal of the second precharge device to provide a delayed version of a clock signal provided at the input of the delay circuit.

### BRIEF DESCRIPTION OF THE DRAWINGS

The embodiments of the present disclosure are illustrated by way of example and not limited by the accompanying figures, in which like references indicate similar elements, and in which:

FIG. 1 is a schematic block diagram view of a prior art multistage domino circuit having an internal delay clock;

FIG. 2 is a timing diagram of the multistage domino circuit of FIG. 1;

FIG. 3 is a schematic block diagram view of a prior art multistage domino circuit having an external delay clock;

FIG. 4 is a timing diagram of the multistage domino circuit of FIG. 3;

FIG. 5 is a schematic block diagram view of a multistage domino circuit having an internal delay clock with an internally generated delay reset clock according to an embodiment of the present disclosure;

FIG. 6 is a timing diagram of the multistage domino circuit of FIG. 5;

FIG. 7 is a schematic block diagram view of a multistage domino circuit having an internal delay clock with an internally generated delay reset clock according to another embodiment of the present disclosure; and

FIG. 8 illustrates a block diagram view of an integrated circuit incorporating a multistage dynamic domino circuit.

Skilled artisans appreciate that elements in the figures are illustrated for simplicity and clarity and have not necessarily been drawn to scale. For example, the dimensions of some of the elements in the figures may be exaggerated relative to other elements to help improve an understanding of the embodiments of the present disclosure.

### DETAILED DESCRIPTION

As will be discussed further herein , the embodiments of the present disclosure remove a prior restriction that the second stage clock (clk_delay) be generated outside of the dynamic block. Accordingly, the embodiments of the present disclosure allow for the second stage clock (clk_delay) to be internally generated. In one embodiment, the second stage includes two p-channel precharge devices. A first precharge device turns off on the rising edge of the clock. The second precharge device is controlled by a delayed version of the same clock. Furthermore, according to another embodiment of the present disclosure, a number of footless stages are daisy chained or cascaded together in a serial arrangement, including daisy chaining the internal delay repeatedly from one stage to a next stage to form a multistage dynamic domino circuit with an internally generated delay reset clock.

Referring again to the figures, FIG. 5 is a schematic block diagram view of a multistage domino circuit 80 having an internal clock delay with an internally generated delay reset clock according to an embodiment of the present disclosure. In particular, multistage dynamic domino logic circuit 80 includes a footed dynamic domino stage 82 and a footless dynamic domino stage 84. Footed dynamic domino stage 82 includes a precharge device 86, for example, a p-channel device. Precharge device 86 receives a clock signal (clk) on signal line 88. Dynamic domino footed stage 82 also includes evaluation logic 90 having data inputs a, b, c, and d, corresponding to reference numerals 92, 94, 96, and 98, respectively. An n-channel device 100 provides for the footed stage of the multistage dynamic domino circuit 80 and has a first terminal coupled between evaluation logic 90 and system ground 110. Clock signal line 88 also couples to a control terminal of footed n-channel device 100.

Footed dynamic domino stage 82 further includes a keeper device 102, for example, a p-channel device. Keeper device 102 includes a control input coupled to an output 104 of stage 82. In addition, an inverter 106 couples between the evaluation logic 90 and output 104. Furthermore, keeper device 102 also includes terminals coupled between system voltage supply potential (V_{DD}) 108 and evaluation logic 90.

Footless dynamic domino stage 84 includes precharge circuit 112 and a delay circuit 118. Precharge circuit 112 includes serially coupled p-channel devices 114 and 116. Clock Delay circuit 118 includes, for example, serially coupled first and second inverters 120,122 for delaying the clock signal (clk) on signal line 88 to provide an output signal (clk_delay) on output signal line 119. Precharge circuit 112 receives first and second input signals corresponding to clock signal (clk) from signal line 88 and a delayed clock (clk_delay) from signal line 119, respectively.

Footless dynamic domino stage 84 also includes evaluation logic 124 having data inputs e and f, corresponding to reference numerals 126 and 128, respectively. Evaluation logic 124 also includes an input coupled to an output of the footed dynamic domino stage 82 at signal line 104. Evaluation logic 124 couples to ground at 110. As shown, evaluation logic 90 and evaluation logic 124 are for illustration purposes only, and can otherwise include any suitable evaluation logic for a particular multistage domino circuit application. Footless dynamic domino stage 84 further includes a keeper device 130, for example, a p-channel device. Keeper device 130 includes a control input coupled to an output 132 of stage 84. In addition, an inverter 134 couples between the evaluation logic 124 and output 132. Furthermore, keeper device 130 also includes terminals coupled between system voltage supply potential (V_{DD}) 108 and evaluation logic 124. Evaluation logic 124 is coupled to system ground via system ground 110, making the stage a footless stage.

FIG. 6 is a timing diagram of the multistage domino circuit 80 of FIG. 5. As shown in FIG. 6, the first timing signal is that of a clock signal (clk) on signal line 88 having a clock period as indicated by reference numeral 142. Reference numeral 144 identifies a rising edge of the clock signal (clk) on signal line 88, corresponding to a beginning of an evaluate phase. Reference numeral 146 identifies a falling edge of clock signal (clk) on signal line 88, corresponding to an end of the evaluate phase and beginning of a precharge phase.

The second timing signal is that of (clk_delay) on signal line 119. Reference numeral 148 identifies a rising edge of clk_delay on signal line 119. Reference numeral 150 identifies a falling edge of clk_delay on signal line 119. The third timing signal is that of the output of footed stage 82 on signal line 104, also corresponding to an input of the evaluation circuit 124. Reference numeral 152 identifies a rising edge of signal on line 104 and reference numeral 154 identifies a falling edge of the signal on line 104. The fourth timing signal is that of the input signal line 128 of the evaluation circuit 124. Reference numeral 156 identifies a rising edge of signal on line 128 and reference numeral 158 identifies a falling edge of the signal on line 128.

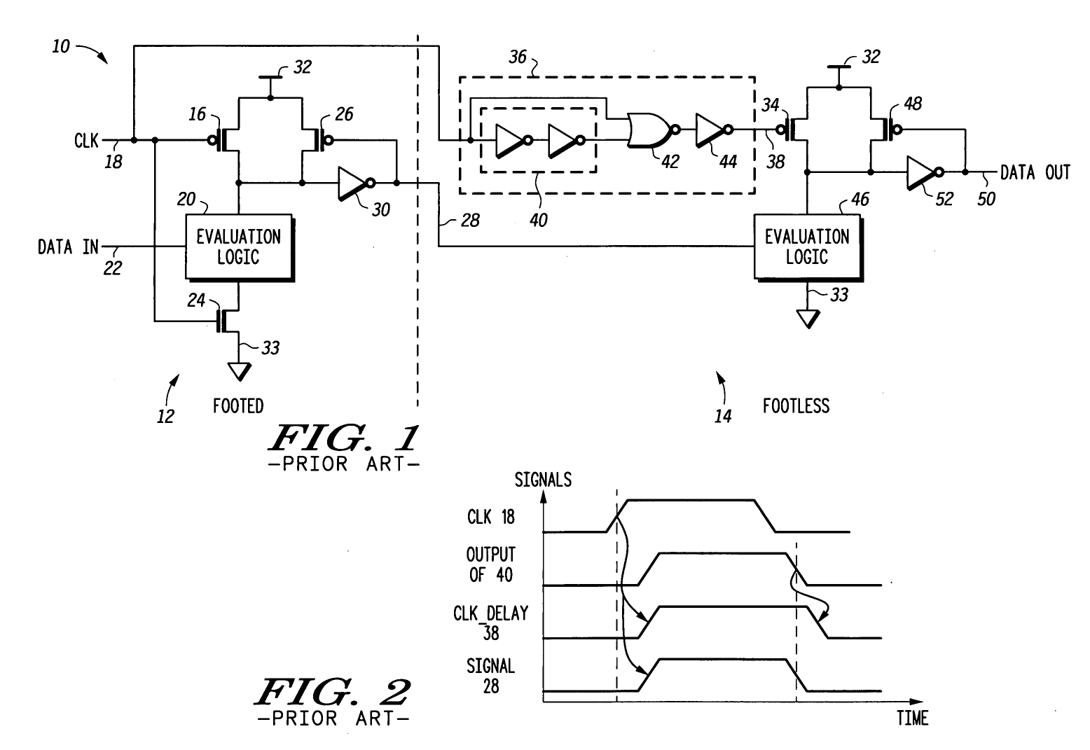

An advantage of circuit 80 of FIG. 5 over the circuit 10 of FIG. 1 is that p-channel device 114 in precharge circuit 112 becomes non-conductive at the rising edge of the clock signal (clk) on line 88 at the start of the evaluate phase. By making p-channel device 114 non-conductive, no race condition exists at either of a) the rising edge 152 of the signal on line 104 or b) the rising edge 156 of the signal on line 128, and the circuit will operate at its maximum frequency unimpaired. In addition, there will be no excess current through circuit 112 and the evaluation logic 124.

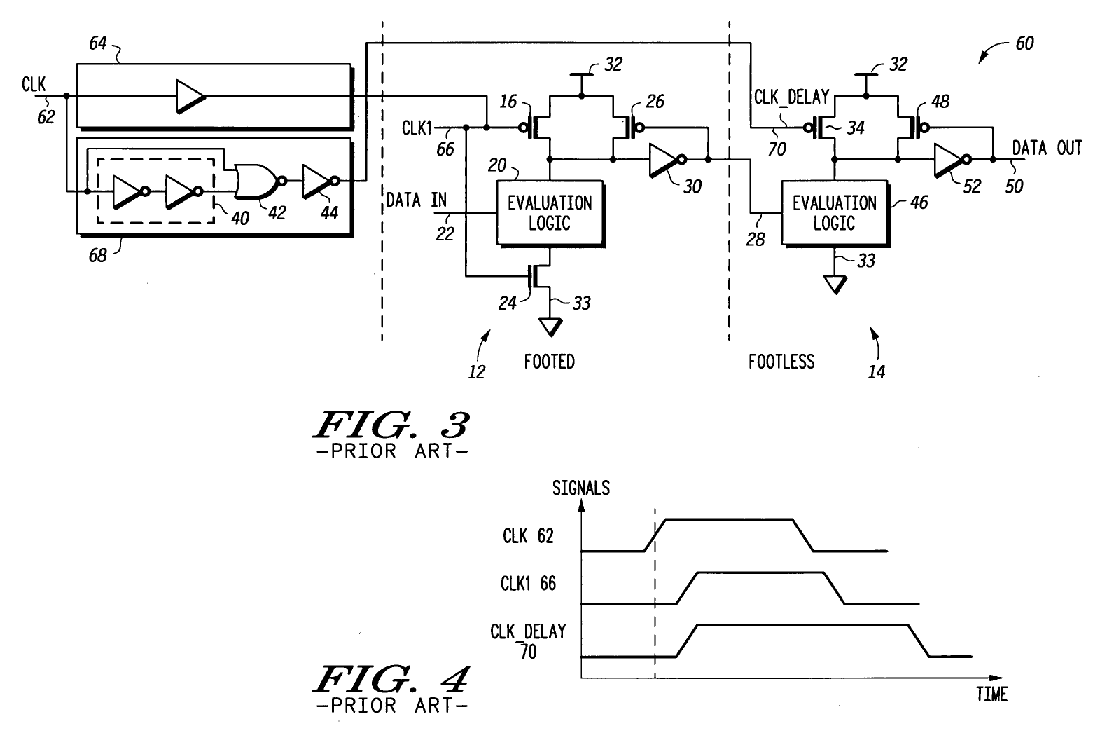

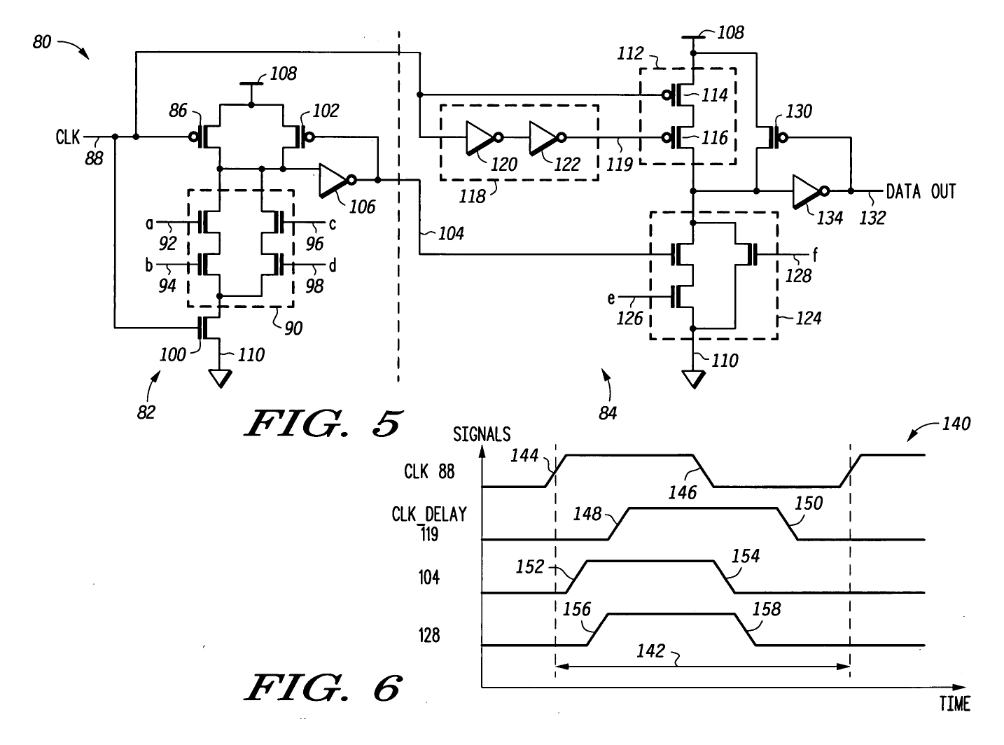

In addition, an advantage of circuit 80 of FIG. 5 over the circuit 60 of FIG. 3 is that p-channel device 116 in precharge circuit 112 becomes conductive after a delay of the falling edge of the clock signal (clk) on line 88 determined by delay circuit 118 at the start of the precharge phase. By making p-channel device 116 conductive after both of a) the falling edge 154 from the signal on line 104 and b) the falling edge 158 from the signal on line 128, the circuit prevents undesired high currents without reference to chip level routing delays or chip level timing issues. In addition, delay circuit 118 can be optimized to track or better match either of signal 104 or 128, whichever signal falls latest. Unlike circuit 80 of FIG. 5, the circuit 60 of FIG. 3 requires a general circuit at the chip level to fit all cases of tracking, thereby preventing circuit 60 from being able to provide the kind of optimization available with circuit 80. In addition, the embodiments of the present disclosure provide for a reduced complexity to the chip design and manufacture thereof.

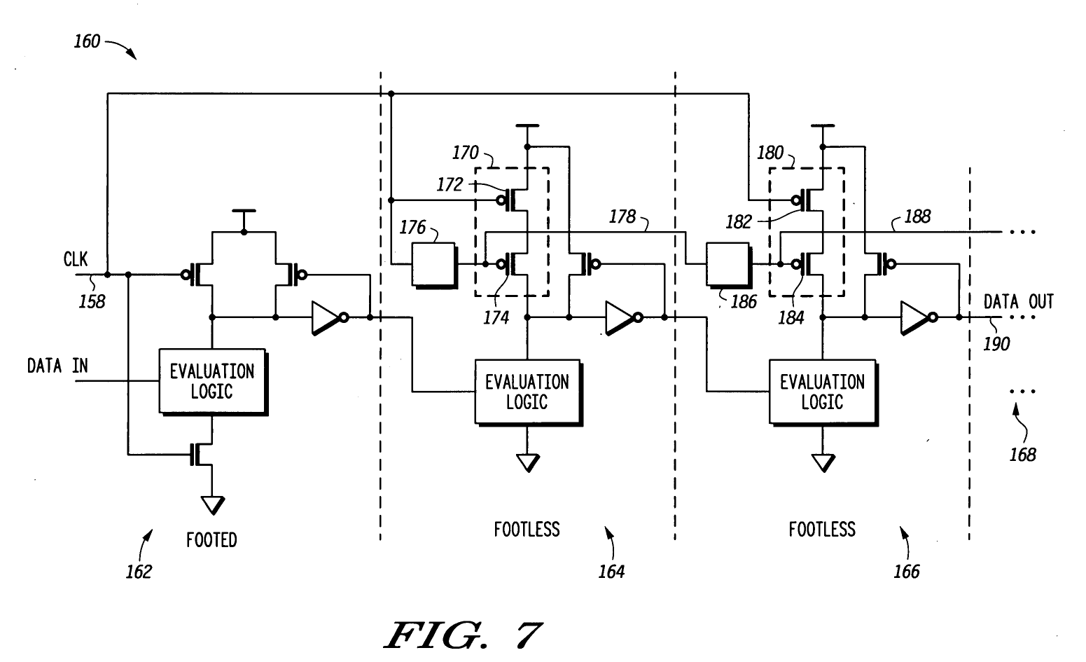

FIG. 7 is a schematic block diagram view of a multistage dynamic domino circuit 160 having an internal clock delay with an internally generated delay reset clock according to another embodiment of the present disclosure. In particular, FIG. 7 illustrates an alternate embodiment that demonstrates an ability to add additional cascaded footless stages to the circuit embodiment of FIG. 5. For example, multistage dynamic domino circuit 160 includes footed stage 162, footless stage 164, footless stage 166, and one or more additional footless stages, as indicated by reference numeral 168. Footed stage 162 is similar to footed stage 82 of FIG. 5 as discussed herein above. Footless stage 164, footless stage 166, and the one or more additional footless stages, as indicated by reference numeral 168, are similar to footless stage 84 of FIG. 5 as discussed herein above, and with differences as noted herein below.

Footless dynamic domino stage 164 includes precharge circuit 170 and a delay circuit 176. Precharge circuit 170 includes serially coupled p-channel devices 172 and 174. Clock delay circuit 176 can include, for example, serially coupled first and second inverters for delaying the clock signal (clk) on signal line 158 and provide an output signal (clk_delay) on an output signal line 178 of the clock delay circuit. Precharge circuit 170 receives first and second input signals corresponding to clock signal (clk) from signal line 158 and a delayed clock (clk_delay) from the output 178 of clock delay circuit 176, respectively. Footless dynamic domino stage 164 also includes evaluation logic that includes an input coupled to an output of the footed dynamic domino stage 162. As shown in FIG. 7, the evaluation logic can include any suitable evaluation logic for a particular multistage domino circuit application.

Footless dynamic domino stage 164 further includes a keeper device, for example, a p-channel device. The keeper device includes a control input coupled to an output of stage 164. In addition, an inverter couples between the evaluation logic and output. Furthermore, the keeper device also includes terminals coupled between system voltage supply potential (V_{DD}) and the evaluation logic. The evaluation logic couples to system ground via a system ground, making the stage a footless stage.

Footless dynamic domino stage 166 includes precharge circuit 180 and a delay circuit 186. Precharge circuit 180 includes serially coupled p-channel devices 182 and 184. Clock delay circuit 186 can include, for example, serially coupled first and second inverters for delaying the clock signal (clk) on signal line 158 and provide an output signal (clk_delay) on an output signal line 188 of the clock delay circuit. Precharge circuit 180 receives first and second input signals corresponding to clock signal (clk) from signal line 158 and a delayed clock (clk_delay) from the output 188 of clock delay circuit 186, respectively. Footless dynamic domino stage 166 also includes evaluation logic that includes an input coupled to an output of the footless dynamic domino stage 164. The evaluation logic of stage 166 can include any suitable evaluation logic for a particular multistage domino circuit application.

Footless dynamic domino stage 166 further includes a keeper device, for example, a p-channel device. The keeper device includes a control input coupled to an output 190 of stage 166. In addition, an inverter couples between the evaluation logic and output 190. Furthermore, the keeper device also includes terminals coupled between system voltage supply potential (V_{DD}) and the evaluation logic. The evaluation logic couples to system ground via a system ground, making the stage a footless stage.

In the embodiment of FIG. 7, the multistage dynamic domino circuit 160 also includes one or more additional footless stages, as indicated by reference numeral 168. The one or more additional footless stages 168 are similar to the footless stages as discussed herein.

Furthermore, with respect to the multistage dynamic domino circuit 160, delay block 186 can also be configured differently. That is, in another alternate embodiment, delay block 186 is not required to be coupled as shown but can be optimized with the clock (clk) on signal line 158 as an input, as opposed to receiving its input from the output 178 of delay block 176. This method would require that delay block 186 take into account a precharge delay greater than an accumulation of all preceeding precharge stages before the output of delay block 186 falls, making p-channel device 184 conductive to supply potential V_{DD}. As shown in FIG. 7, there exists two preceeding precharge stages before delay block 186, but there could be more if the delay block were that of an additional subsequent cascaded footless stage. Accordingly, this method of accounting for accumulated precharge delay applies similarly with respect to any additional cascaded footless stages.

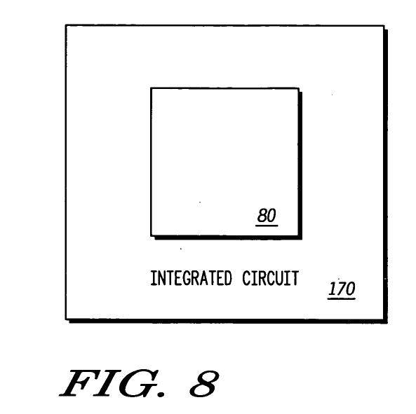

FIG. 8 illustrates a block diagram view of an integrated circuit 170 incorporating a multistage dynamic domino circuit 80 as shown and discussed with respect to FIG. 5. Alternatively, circuit 170 can incorporate a multistage dynamic domino circuit 160 as shown and discussed with respect to FIG. 7. Integrated circuit 170 can include, for example, one or more of various processor and peripheral devices incorporated in system-on-chip (SOC) designs.

According to one embodiment, the multistage domino circuit includes two series p-channel devices and a delay chain within at least the second stage to allow for internal generation and control of the delay reset falling edge only. Accordingly, the requirement for an external pulse generator as implemented in the prior art is no longer needed. Rather, according to the present embodiments, internal circuits as described herein resolve the difficult timing and integration issues of the external pulse generator implementations.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements by may include other elements not expressly listed or inherent to such process, method, article, or apparatus.

1. A multistage dynamic domino circuit comprising:
a footed dynamic domino stage including:
a first precharge circuit;
evaluation logic; and
a data output coupled to the evaluation logic;
a footless dynamic domino stage including:
evaluation logic including a data input coupled to the data output of the footed dynamic domino stage; and
a second precharge circuit including:
a first precharge device including a first current terminal and a control terminal coupled to a clock line; and
a second precharge device including a first current terminal coupled to the first current terminal of first precharge device and a control terminal; and
a delay circuit including an input coupled to the clock line and an output coupled to the control terminal of the second precharge device to provide a delayed version of a clock signal provided at the input of the delay circuit.

2. The circuit of claim 1 wherein the first precharge circuit includes a P-channel device having control terminal coupled to the clock line.

3. The circuit of claim 1 wherein the delay circuit includes:
a first invertor including an input coupled to the input of the delay circuit and an output; and
a second input including an input coupled to the output of the first inverter and the output coupled to the output of the delay circuit.

4. The circuit of claim 1 wherein:
the footed dynamic domino delay stage has a falling edge delay from a precharge edge of a clock signal provided to the precharge circuit of the footed dynamic domino stage to a falling edge of the data output; and
the delay circuit providing the delayed version with a delay of greater than the falling edge delay.

5. The circuit of claim 4 where the first precharge circuit is coupled to the clock line, wherein the clock signal is provided to the first precharge circuit via the clock line.

6. The circuit of claim 1 wherein:
the control terminal of the first precharge device is connected to the clock line;
the input of the delay circuit is connected to the clock line; and
the output of the delay circuit is connected to the control terminal of the second precharge device.

7. The circuit of claim 6 wherein the first precharge circuit of the footed dynamic domino circuit includes a third precharge device including a control terminal, the control terminal of the third precharge device is connected to the clock line.

8. The circuit of claim 1 wherein during a precharge phase following an evaluation phase, the output of the delay circuit falls after a falling edge of the data output occurring during the precharge phase.

9. The circuit of claim 1 wherein entering an evaluation phase, the control terminal of the first precharge device receives a rising edge prior to a rising edge of the data out during the evaluation phase.

10. The circuit of claim 1 further comprising:
a second footless dynamic domino stage including:
evaluation logic including a data input coupled to a data output of the footed dynamic domino stage; and
a third precharge circuit including:
a third precharge device including a first current terminal and a control terminal coupled to the clock line; and
a fourth precharge device having a first current terminal coupled to the first current terminal of third precharge device and a control terminal; and
a second delay circuit including an input coupled to the clock line and an output coupled to the control terminal of the fourth precharge device to provide a delayed version of a clock signal provided to the input of the second delay circuit.

11. The circuit of claim 10 wherein the input of the second delay circuit is coupled to the clock line via the delay circuit.

12. The circuit of claim 11 wherein the output of the second delay circuit provides a delayed version of the delay version of the clock signal provided at the input of the delay circuit.

13. The circuit of claim 10 wherein during a precharge phase following an evaluation phase, the output of the second delay circuit falls after a falling edge of the data output of the footless dynamic domino stage occurring during the precharge phase.

14. The circuit of claim 10 wherein:
the first precharge device includes a first P-channel device;
the second precharge device includes a second P-channel device;
the third precharge device includes a third P-channel device;
the fourth precharge device includes a fourth P-channel device.

15. The circuit of claim 1 wherein the delay circuit and the footless dynamic domino stage are implemented in a single custom block of an integrated circuit.

16. The circuit of claim 1 wherein:
the first precharge device includes a first P-channel device;
the second precharge device includes a second P-channel device.

17. An integrated circuit including the multistage dynamic domino circuit of claim 1.

18. The integrated circuit of claim 17 further comprising:
a processor, wherein the processor includes the multistage dynamic domino circuit.

19. A method of operating a multistage dynamic domino circuit, the method comprising:
making non conductive a first precharge device of a footed dynamic domino stage to enter an evaluation phase, wherein the first precharge device is located in a first current path between evaluation logic of the footed dynamic domino stage and a voltage supply;
making non conductive a second precharge device of a footless dynamic domino stage concurrently with the making non conductive the first precharge device, wherein the second precharge device is located in a second current path between evaluation logic of the footless dynamic domino stage and a voltage supply, wherein the evaluation logic of the footed dynamic domino stage is coupled to the evaluation logic of the footless dynamic domino stage;
making conductive the first precharge device after the making non conductive non conductive the first precharge device to enter a precharge phase after the evaluation phase, wherein the making the first precharge device conductive makes conductive the first current path between the evaluation logic and the voltage supply;
making conductive the second precharge device concurrently with the making conductive the first precharge device;
making conductive a third precharge device located in the second current path after the making conductive the second precharge device, wherein the making conductive the third precharge device makes conductive the second current path between the evaluation logic of the footless dynamic domino stage and the voltage supply.

20. The method of claim 19 wherein:
the first precharge device and the second precharge device each include a control terminal coupled to a clock line, wherein the making non conductive the first precharge device and the making non conductive the second precharge device include transitioning a clock signal provided on the clock line from a first state to a second state,
the making conductive the first precharge device and the making conductive the second precharge device include transitioning the clock signal from the second state to the first state;
the method further comprises delaying the clock signal to produce a delayed clock signal and providing the delayed clock signal to a control terminal of the third precharge device.

21. The method of claim 19 further comprising:
making non conductive a fourth precharge device of a second footless dynamic domino stage concurrently with the making non conductive the first precharge device, wherein the fourth precharge device is located in a third current path between evaluation logic of the second footless dynamic domino stage and a voltage supply, wherein the evaluation logic of the footless dynamic domino stage is coupled to evaluation logic of the second footless dynamic domino stage;
making conductive a fifth precharge device located in the third current path after the making conductive the fourth precharge device, wherein the making conductive the fifth precharge device makes conductive the third current path between the evaluation logic of the second footless dynamic domino stage and the voltage supply.

22. The method of claim 21 wherein the making conductive the fifth precharge device occurs during a precharge phase following an evaluation phase after a falling edge of a data output of the footless dynamic domino stage occurring during the precharge phase, the data output of the footless dynamic domino stage is coupled to the evaluation logic of the second footless dynamic domino stage.

23. The method of claim 19 wherein the making conductive the third precharge device occurs during a precharge phase following an evaluation phase after a falling edge of a data output of the footed dynamic domino stage occurring during the precharge phase, the data output of the footed dynamic domino stage is coupled to the evaluation logic of the footless dynamic domino stage.

24. The method of claim 19 wherein:
the first precharge device includes a first P-channel device;
the second precharge device includes a second P-channel device;
the third precharge device includes a third P-channel device.

25. A multistage dynamic domino circuit comprising:
a footed dynamic domino stage including:
a first precharge circuit including a P-channel device, the P-channel device including a control terminal coupled to a clock line;
evaluation logic including at least one N-channel device; and
a data output coupled to the evaluation logic;
a footless dynamic domino stage including:
evaluation logic including a data input coupled to the data output of the footed dynamic domino stage, the evaluation logic including at least one N-channel device; and
a second precharge circuit including:
a second P-channel device including a first current terminal and a control terminal coupled to the clock line; and
a third P-channel device having a first current terminal coupled to the first current terminal of second P-channel device and a control terminal; and
a delay circuit including an input coupled to the clock line and an output coupled to the control terminal of the third P-channel device to provide a delayed version of a clock signal provided on the clock line.
